(19) United States
(12) Patent Application Publication
(10) Pub. No.: US 2024/0203838 A1
(43) Pub. Date: Jun. 20, 2024

(54) ULTRA-LOW THICKNESS SEMICONDUCTOR PACKAGE

(71) Applicant: Texas Instruments Incorporated, Dallas, TX (US)

(72) Inventors: Huo Yun Duan, Chengdu (CN); Fu Ren Pang, Chengdu (CN); Zheng Qing Fan, Chengdu City (CN); Silijia Xie, Kunming (CN)

(21) Appl. No.: 18/069,220

(22) Filed: Dec. 20, 2022

(51) Int. Cl. H01L 23/495; H01L 23/00; H01L 23/31

(52) U.S. Cl. CPC H01L 23/49541; H01L 23/3107; H01L 23/49503; H01L 24/48; H01L 2224/48245

(57) ABSTRACT

An example integrated circuit (IC) package comprises a DAP having a diamond shape with four corners. The DAP has a first thickness. The IC package has at least one tie bar segment attached to a corner of the DAP. The at least one tie bar segment extends from the DAP to an edge of the IC package. The IC package has at least one contact portion positioned adjacent to a side of the DAP. The at least one contact portions has a second thickness that is greater than the first thickness of the DAP. A semiconductor die mounted on the DAP. A wire bond couples a bond pad on the semiconductor die and a selected one of the contact portions. A molding compound covers the semiconductor die and the bond wire and at least a portion of the DAP and the at least one contact portion.

### BACKGROUND

Leadframe strips are used in manufacturing packaged integrated circuits. Leadframe strips are comprised of multiple individual leadframe sections that are connected together by tie bars. An embedded leadframe strip is a leadframe strip to which integrated circuit dies are attached and then embedded in molding compound. Leadframe strips may include a semiconductor die attachment pad for attaching an integrated circuit die. The leadframe sections can be mechanically connected for stability during processing but are then separated prior to completion of the packaging process. Terminals on the integrated circuit dies may be electrically connected to leadframe leads and/or to other integrated circuit dies prior to completion of the packaged integrated circuit. In some packaged integrated circuits, bond wires are used to couple the terminals on the integrated circuit dies to leads on the leadframes and to other integrated circuit dies.

Semiconductor devices including active and/or passive components may be manufactured into round wafers sliced from elongated cylinder-shaped single crystals of semiconductor elements or compounds. The diameter of these solid-state wafers may reach up 12 inches or more. Individual semiconductor dies are typically singulated from a round wafer by sawing streets in X- and Y-directions through the wafer in order to create rectangularly shaped discrete pieces from the wafers.

Each semiconductor die includes at least one active or passive component and die pads serving to facilitate electric connections to the component(s) of the semiconductor die. Semiconductor dies include many large families of electronic components; examples include active devices such as diodes and transistors like field-effect transistors, passive devices such as resistors and capacitors, and integrated circuits, which can include far more than a million active and passive components.

After singulation, one or more semiconductor dies are attached to a discrete supporting substrate such as a metal leadframe. The conductive traces of the leadframes and substrates are connected to the die pads, typically using bonding wires or metal bumps such as solder bumps.

The assembled semiconductor dies, leadframes and/or substrates may be encapsulated to form discrete robust packages, which frequently employ hardened polymeric compounds and are formed by techniques such as transfer molding. The assembly and packaging processes are performed either on an individual basis or as part of batch processes including a strip or array of semiconductor dies on a corresponding strip or array of leadframes and/or through a single loading of a mold press.

### SUMMARY

In an arrangement, a semiconductor package comprises a die mounting portion having a quadrilateral shape with four corners. The die mounting portion has a first thickness. A tie bar segment is attached to each corner of the die mounting portion. Each tie bar segment extends from the die mounting portion to an edge of the semiconductor package. The semiconductor package includes four lead portions. Each individual lead portion is positioned adjacent to a separate side of the die mounting portion. The four lead portions each have a second thickness that is greater than the first thickness of the die mounting portion. The semiconductor package has a semiconductor die mounted on the die mounting portion. Four wire bonds have a first end bonded to a separate bond pad on the semiconductor die and a second end bonded to a separate lead portion. The semiconductor package has a molding compound covering the semiconductor die and the bond wires. The molding compound covers at least a portion of the die mounting portion and of the four lead portions.

The semiconductor package has a rectangular shape with the die mounting portion having a diamond shape generally centered within the semiconductor package. Each of the four lead portions have a sloped side that is generally parallel to a side of the die mounting portion.

In an embodiment, the first thickness of the four lead portions is 8 mil and the second thickness of the die mounting portion is 4 to 5 mil. The first thickness is a thickness of a leadframe panel used in manufacturing the semiconductor package, and the second thickness is created by partially etching the leadframe panel. The tie bar segments attached to each corner of the die mounting portion has the second thickness that is created by partially etching the leadframe panel.

The semiconductor package has a notch in one side of the die mounting portion.

A bottom surface of the die mounting portion and bottom surfaces of the four lead portions are exposed through the molding compound of the semiconductor package. The tie bar segments attached to each corner of the die mounting portion and contact tie bars attached the four lead portions are exposed through the molding compound on sides of the semiconductor package.

In another arrangement, an integrated circuit (IC) package comprises a DAP having a diamond shape with four corners. The DAP has a first thickness. The IC package has at least one tie bar segment attached to a corner of the DAP. The at least one tie bar segment extends from the DAP to an edge of the IC package. The IC package has at least one contact portion. The at least one contact portion is positioned adjacent to a side of the DAP. The at least one contact portions has a second thickness that is greater than the first thickness of the DAP. A semiconductor die mounted on the DAP. A wire bond in the IC package has a first end bonded to a bond pad on the semiconductor die and a second end bonded to a selected one of the at least one contact portion. A molding compound covers the semiconductor die and the bond wire. The molding compound covers at least a portion of the DAP and of the at least one contact portion. The IC package has a rectangular shape with the DAP generally centered within the IC package. The at least one contact portion is located near a corner of the IC package. The at least one contact portion has a side that is generally parallel to a side of the DAP. The at least one tie bar segment attached to the corner of the DAP has the second thickness. The IC package further comprises additional tie bar segments attached to the at least one contact portion. The additional tie bar segments have a third thickness that is created by partially etching the leadframe panel. A notch on one side of the DAP is adjacent to the at least one contact portion. The bottom surface of the DAP and the bottom surface the at least one contact portion are exposed through the molding compound. The at least one tie bar segment attached to the corner of the DAP and the additional tie bar segments attached to the at least one contact portion are exposed through the molding compound on sides of the IC package. The IC package may comprise a Quad Flat No-lead (QFN) package with four contacts.

### BRIEF DESCRIPTION OF THE DRAWINGS

Having thus described the invention in general terms, reference will now be made to the accompanying drawings, wherein:

FIG. 1 illustrates a portion of a leadframe strip 100 for an ultra-low thickness semiconductor package.

FIG. 2 is a top view of an ultra-low thickness semiconductor package that is manufactured using leadframe sheet 100 as illustrated in FIG. 1.

FIG. 3 is a cross section view of the ultra-low thickness semiconductor package shown in FIG. 2.

FIG. 4 is a view illustrating the bottom side 401 of the ultra-low thickness semiconductor package.

FIG. 5 is a schematic top plan view of a leadframe strip for use in implementing the ultra-low thickness semiconductor package disclosed herein.

### DETAILED DESCRIPTION

The present disclosure is described with reference to the attached figures. The figures are not drawn to scale, and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

Corresponding numerals and symbols in the different figures generally refer to corresponding parts, unless otherwise indicated. The figures are not necessarily drawn to scale. In the drawings, like reference numerals refer to like elements throughout, and the various features are not necessarily drawn to scale. In the following discussion and in the claims, the terms “including,” “includes,” “having,” “has,” “with,” or variants thereof are intended to be inclusive in a manner similar to the term “comprising,” and thus should be interpreted to mean “including, but not limited to . . . ” Also, the terms “coupled,” “couple,” and/or or “couples” is/are intended to include indirect or direct electrical or mechanical connection or combinations thereof. For example, if a first device couples to or is electrically coupled with a second device that connection may be through a direct electrical connection, or through an indirect electrical connection via one or more intervening devices and/or connections. Elements that are electrically connected with intervening wires or other conductors are considered to be coupled. Terms such as “top,” “bottom,” “front,” “back,” “over,” “above,” “under,” “below,” and such, may be used in this disclosure. These terms should not be construed as limiting the position or orientation of a structure or element but should be used to provide spatial relationship between structures or elements.

The term “semiconductor die” is used herein. A semiconductor device can be a discrete semiconductor device such as a bipolar transistor, a few discrete devices such as a pair of power FET switches fabricated together on a single semiconductor die, or a semiconductor die can be an integrated circuit with multiple semiconductor devices such as the multiple capacitors in an A/D converter. The semiconductor device can include passive devices such as resistors, inductors, filters, sensors, or active devices such as transistors. The semiconductor device can be an integrated circuit with hundreds or thousands of transistors coupled to form a functional circuit, for example a microprocessor or memory device. The semiconductor device may also be referred to herein as a semiconductor device or an integrated circuit (IC) die.

The term “semiconductor package” is used herein. A semiconductor package has at least one semiconductor die electrically coupled to terminals and has a package body that protects and covers the semiconductor die. In some arrangements, multiple semiconductor dies can be packaged together. For example, a power metal oxide semiconductor (MOS) field effect transistor (FET) semiconductor device and a second semiconductor device (such as a gate driver die, or a controller die) can be packaged together to from a single packaged electronic device. Additional components such as passive components, such as capacitors, resistors, and inductors or coils, can be included in the packaged electronic device. The semiconductor die is mounted with a package substrate that provides conductive leads. A portion of the conductive leads form the terminals for the packaged device. In wire bonded integrated circuit packages, bond wires couple conductive leads of a package substrate to bond pads on the semiconductor die. The semiconductor die can be mounted to the package substrate with a device side surface facing away from the substrate and a backside surface facing and mounted to a die pad of the package substrate. The semiconductor package can have a package body formed by a thermoset epoxy resin mold compound in a molding process, or by the use of epoxy, plastics, or resins that are liquid at room temperature and are subsequently cured. The package body may provide a hermetic package for the packaged device. The package body may be formed in a mold using an encapsulation process, however, a portion of the leads of the package substrate are not covered during encapsulation, these exposed lead portions form the terminals for the semiconductor package. The semiconductor package may also be referred to as a “integrated circuit package,” a “microelectronic device package,” or a “semiconductor device package.”

It is desirable in some arrangements for a semiconductor package to have a low or ultra-low profile. The semiconductor packages height or thickness is determined at least in part by the thickness of the leadframe and the package devices, such as a semiconductor die. Common leadframe material sizes include leadframes with thicknesses of 5 mil (127 um), 6 mil (152 um), 8 mil (203 um), and 10 mil (254 um), where “mil” is 1/1000 inches. The height or thickness of an ultra-low semiconductor package is a maximum of 400 um. In one design, a thin leadframe with a 5 mil thickness is used to avoid exposing leadframe metal in the final package. However, a 5 mil leadframe can be subject to low availability, high price, and size constraints compared to a standard 8 mil leadframe. Given that there are more suppliers for the 8 mil leadframe, which results in lower prices, a low profile semiconductor package using an 8 mil leadframe would be advantageous. Additionally, the 8 mil leadframe allows for more units per strip and standardized tools can be used, such as saw blades used for singulation.

The maximum mold cap (i.e., the distance between the top surface of the lead frame and the top surface of the package body) for an ultra-thin QFN package (X2QFN) with a 5 mil (127 um) lead frame is 270 um, total package thickness is 127+270=397 um. If the lead frame thickness is 8 mils (203 um), then the total package thickness using this mold cap will be 203+270=473 um. This total thickness will be out of the X2QFN package thickness specification of which has a maximum thickness of 400 um. In order to keep the total package thickness less than 400 um, the mold cap needs to be reduced from 270 um to 194 um, so that total thickness of the package can be 203+194=397 um.

In an arrangement described below, a low profile package having an ultra-low thickness uses an 8 mil leadframe. The 8 mil leadframe provides increased strength to eliminate deformation during manufacturing. Portions of the 8 mil leadframe are etched to a thickness of 4-5 mils to avoid exposing the semiconductor die and bond wire loops. The solution disclosed herein can be implemented in all QFN packages, especially in ultra-thin QFN packages. If the die-surface to package-surface clearance is too small, issues such as exposed wires, exposed dies, or incomplete fill will arise. The proposed solution is used to increase the die-surface to package-surface clearance and can be applied to all kinds of wafers for manufacturing different semiconductor devices. The solution proposes a new design of a lead frame to replace conventional lead frames in the industry. Concepts of the design details include increasing the overall thickness of the lead frame. For example, changing lead frame thickness from 5 mil to 8 mil to increase the lead frame strength to eliminate deformation during manufacturing and improvement yield. Another feature is reducing the thickness of the die pad compared to the overall thickness of the lead frame. For example, in the 8-mil lead frame, changing the die pad thickness from 8 mil to 4 mil provides a die attach region horizontally lower than a top surface of the lead frame to receive the silicon die and bond wires to avoid exposing the die and exposing wires.

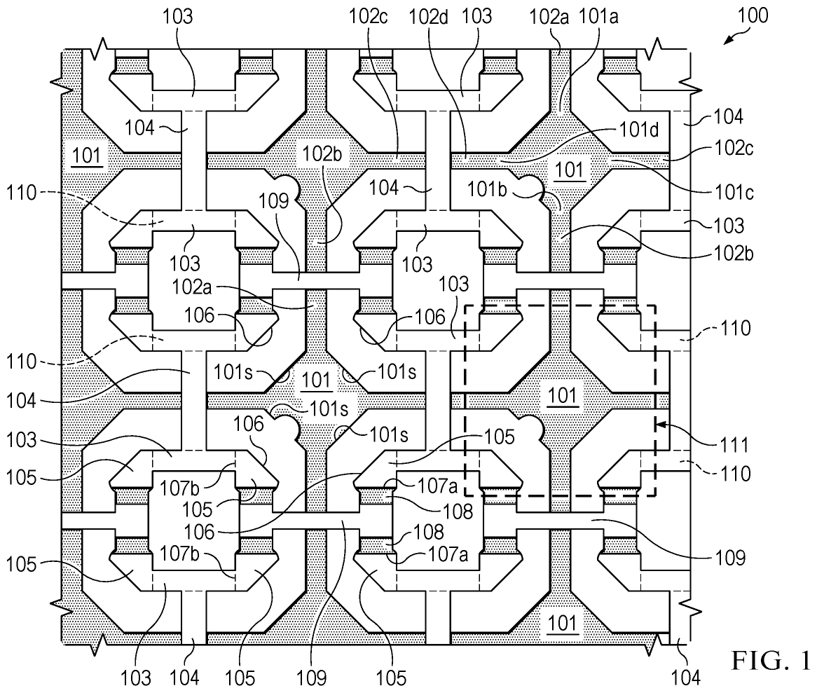

FIG. 1 illustrates a portion of a leadframe strip 100 for an ultra-low thickness semiconductor package. Leadframe strip 100 has a plurality of interconnected die attach pad (DAP) portions 101. Each DAP 101 is a quadrilateral and is positioned like a diamond on leadframe strip 100. In one arrangement, DAPs 101 have with generally square dimensions but other arrangements, such as quadrilaterals that do not have parallel shapes are also possible. Two corners 101a, 101b of each DAP 101 are oriented north-south on the leadframe strip 100. The other two corners 101c, 101d on each DAP 101 are oriented east-west on leadframe strip 100. Tie bars 102a-d are attached to each of the four corners 101a-d of DAP 101. As used herein, the term “tie bar” refers to a portion of leadframe 100 that is directly connected to, and mechanically supports, segments such as DAP 101 or lead portions 103 during packaging. The tie bars may connect the segments to each other or to a peripheral leadframe member or side rail (not shown), for example. The tie bars may have a uniform or non-uniform width.

Leadframe strip 100 has a plurality of lead portions 103 that are linked together by cross tie bars 104 that are attached to a central portion of lead portion 103. There are two contact portions 105 on opposing ends of each lead portion 103. The contact portions have a cross-section shape that is generally rectangular with a corner cut off to form a sloped side 106. The sloped side 106 of each contact 105 faces a DAP 101 and is generally parallel to a side 101s of the DAPs 101. The contacts 105 have a first side 107a that is attached to a tie bar segment 108. Tie bar segments 108 are in turn attached to each other via a cross tie bar 109. The contacts 105 also have a second side 107b that is attached to the center section 110 of lead portion 103. Each lead portion 103 is coupled to other lead portions by north-south oriented cross tie bars 104 and by east-west oriented cross tie bars 109. The north-south oriented cross tie bars 104 are attached to DAP tie bars 102c, 102d. The east-west oriented cross tie bars 109 are attached to DAP tie bars 102a, 102b.

In one arrangement, a blank 8 mil leadframe panel is patterned to define the DAPs 101, lead portions 103, tie bars 102a-d, 104, 109, and tie bar segments 108 of leadframe strip 100. The panel may be patterned using conventional techniques such as etching, stamping, or a combination of the two. Portions of the leadframe strip 100 may be further processed to create recesses that are about half of the panel thickness. A leadframe with portions of such recess is often referred to as half-etched or partially etched leadframe. For example, a top surface of DAPs 101, tie bars 102a-d, and tie bar segments 108 on leadframe strip 100 may be half etched to give these areas a thickness of approximately 100 um. The remaining portions of leadframe strip 100, such as lead portions 103 and cross tie bars 104, may a thickness of approximately 200 um. In some arrangements, the bottom side of the leadframe strip 100 may also be partially etched to reduce the thickness of additional areas. In leadframe strip 10, the underside of center section 110 on lead portions 103 may be partially etched between contacts 105 so that the center section 110 is thinner than the contacts 105.

During the manufacturing process, integrated circuit dies (not shown) are mounted to the top surface DAPs 101 using a die attach material, such as paste or film. Bond wires are attached to electrically connect terminals of the integrated circuit dies to contacts 105. Portions of the integrated circuit dies, the bond wires, and the leadframe strip 100 are encapsulated in a mold compound or encapsulant material (not shown). The DAP portions 101 are spaced from one another by saw streets. Saw streets are defined areas of the leadframe strip 100 where groups of integrated circuit devices can be separated in a later process step by cutting through the saw street to form sections. Upon the hardening of the mold compound, leadframe sections, such as section 111, within the leadframe strip 100 are cut apart or singulated for producing individual packages. Such singulation is typically accomplished via a sawing process. In a conventional mechanical saw process, a saw blade (or dicing blade) is typically advanced along saw streets which extend in prescribed patterns between the leadframe sections to separate the leadframe sections from one another.

Leadframe strip 100 may be fabricated from a copper sheet that is etched or stamped to form a pattern of DAP portions, contacts, leads, and tie bars. Leadframe strip 100 may be plated with tin or another metal that will prevent oxidation of the copper and provide a lower contact surface that is easy to solder. The backside of leadframe strip may include a solderable metal layer on a base metal. Leadframe strip 100 can be provided to a packaging process including a pre-plated material that includes the solderable metal layer. Alternatively, the solderable metal layer can be applied to the base metal of leadframe strip 100 at a prior step in the packaging process. The solderable metal layer on the backside surface of the contacts 105 and the DAP portions 101 form external terminals that are used to electrically connect to the integrated circuit dies.

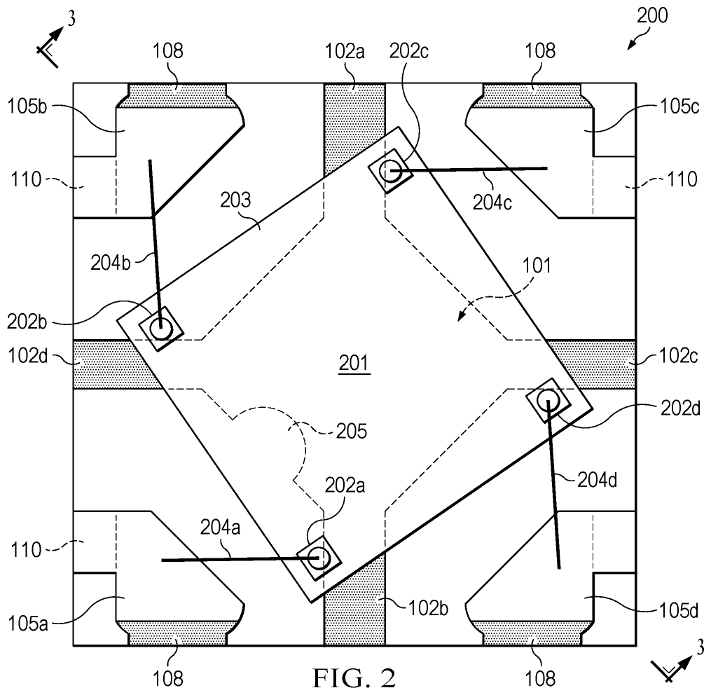

FIG. 2 is a top view of an ultra-low thickness semiconductor package 200 that is manufactured using leadframe sheet 100 as illustrated in FIG. 1. Semiconductor package 200 may be singulated section of leadframe sheet 100, such as section 111. A semiconductor die 201 is mounted on DAP 101 using a die attach film or paste. Semiconductor die 201 has a number of bond pads 202a-d on a top surface 203. The bond pads 202a-d are electrically coupled to respective contacts 105a-d the leadframe sheet using bond wires 204a-d.

To ensure the desired orientation of semiconductor die 201 and proper connections between individual bond pads 202a-d and contacts 105a-d, DAP 101 has a notch 205 that is positioned to indicate which contact 105a-d is “Pin 1” on leadframe sheet 101. As shown in FIG. 2, the notch 205 faces contact 105a. During the manufacturing process, semiconductor die 201 will be oriented on DAP 101 so that the corresponding bond pad 202a for Pin 1 will be positioned close to contact 105a. This will result in bond pad 202a being coupled to contact 105a when bond wire 204a is attached. Although shown as a semicircle in the figures, in other arrangements the notch 205 may have other shapes, such as triangular or rectangular notches.

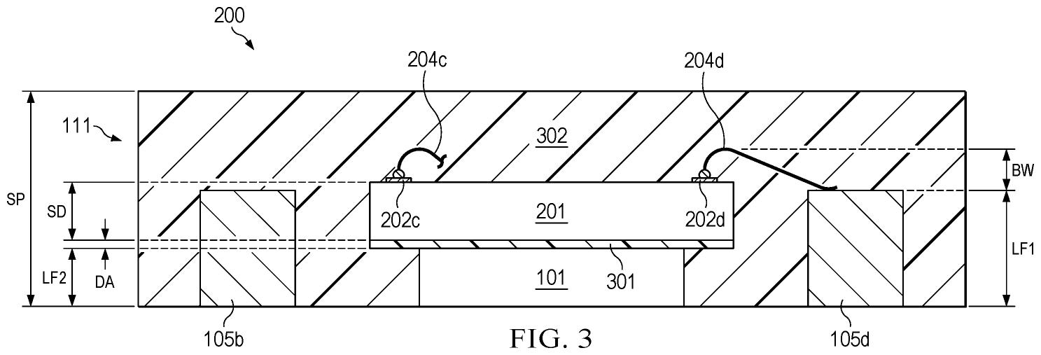

FIG. 3 is a cross section view of the ultra-low thickness semiconductor package 200 shown in FIG. 2. As illustrated in FIG. 3, semiconductor die 201 is mounted on DAP 101 using die attach film or paste 301. DAP 101 is formed by partially etching a portion of the leadframe, while contacts 105b, 105d are unetched and have the thickness of the original leadframe panel. A mold compound 302, such as an epoxy mold material, encapsulates the leadframe section 111, semiconductor die 201, contacts 105a-d, and bond wires 204a-d to form the semiconductor package 200.

In one arrangement, the original leadframe and the contacts 105b, 105d have a thickness LF1 of 8 mils or approximately 200 um. The partially etched or half etched DAP 101 has a thickness LF2 of 4 mils or approximately 100 um. Semiconductor die 201 has a thickness SD of 100 um. Die attach film 301 has a thickness DA of 10 um to 25 um. The loops for bond wires 204c, 204d have a height BW of approximately 55 um. This keeps the overall height SP of semiconductor package 200 below a maximum of 400 um while still ensuring that all of the components are covered by mold compound 302.

In the example arrangement, the proposed lead frame includes die pad 101 having a surface horizontally lower than a surface of the leads 105a-d. The die pad may have a 4-5.5 mil (101-139 um) half etch on the top surface. This design meets total package thickness requirement and keeps enough clearance to make sure there is no exposed die or exposed wire. The tie bars may also be at least partially half etched together with the die pad. The concept can also be applied to other types of QFN lead frames with different numbers of leads to reduce the thickness of the QFN package. Also, the size (surface area width×length) of the die pad 101 may be smaller than size of the silicon die, or the size of the die pad can be equal to or greater than the size of the silicon die.

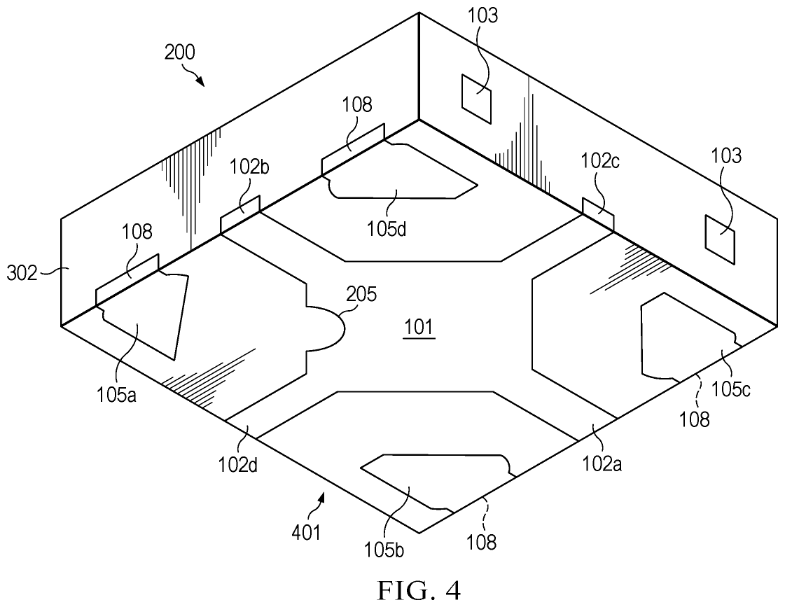

FIG. 4 is a view illustrating the bottom side 401 of the ultra-low thickness semiconductor package 200. The bottom side of DAP 101 and contacts 105a-d are exposed for connection to other devices. Tie bars 102a-d are also exposed. But after singulation into an individual unit 200, tie bars 102a-d are no longer connected to contacts 105a-d. Parts of lead portions 103 and tie bar segments 108 are also exposed on the sides of mold compound 302 and are coupled to the nearest contact 105a-d.

In the ultra-low thickness semiconductor package 200, contacts 105a-d are the package terminals. Contacts 105a-d are not shaped as conventional cantilevered leads but flat metal pins. Accordingly, the embodiment is classified as a Quad Flat No-lead (QFN) or a Small Outline No-lead (SON) package. Following widespread usage, package terminals 105a-d are referred to as pins in spite of the fact that they have a flat surface and do not resemble pointed objects. In the embodiment shown, the metal pins 105a-d are coplanar with the surrounding plastic surface of the mold compound 302. In other embodiments, the pins 105a-d may protrude a step of about 0.05 mm from the mold compound surface.

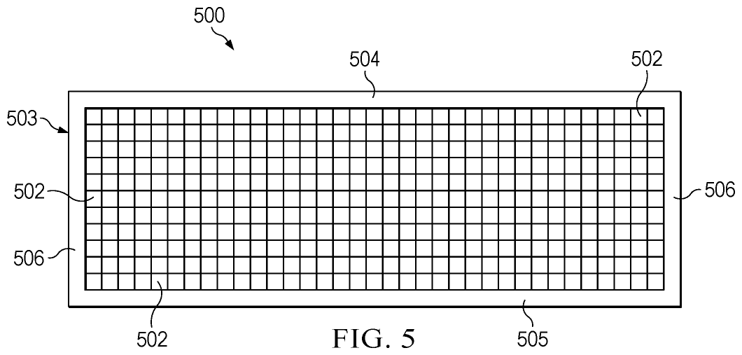

FIG. 5 is a schematic top plan view of a leadframe strip 500 for use in implementing the ultra-low thickness semiconductor package disclosed herein. Leadframe strip 500 is 8 mils thick, which allows for a single panel without wasting metal for spacer or support bars between panels. Leadframe strip 501 is arranged in a grid of integrally connected leadframe units 502. In the example of FIG. 5, the units 502 are square, but it may have other shapes in other examples. In one arrangement, leadframe units 502 comprise a 227×65 array, but the number of leadframe units in any particular leadframe panel or strip is a matter of design choice and is typically greater than that shown schematically in FIG. 5. The leadframe strip 500 has a peripheral border portion 503 including a top rail 504, a bottom rail 505, and opposite end rails 506. Each of the leadframe units 502 correspond to a layout such as section 111 (FIG. 1) having at least one centrally positioned die attachment pad 101 and a plurality of peripheral leads 105.

In arrangements disclosed herein, using a leadframe with thickness mil 8 mil instead of thinner leadframe such as 5 mil provides increased leadframe strength, which eliminates leadframe deformation during manufacturing. The 8 mil leadframe die attach pad is partially etched to a 4-5 mil thickness. This allows a semiconductor die to be coupled to leadframe contacts with a bond wire loop without exposing the die or bon wire from a mold compound in a final semiconductor package. The use of a standardized leadframe panel thickness expands the number of suppliers, reduces the need for tool conversion (e.g., saw blade) during manufacturing, improves overall equipment usage during manufacturing and mold process, and increases the number of units 502 per strip 500.

A semiconductor package according to one arrangement comprises a die mounting portion having a quadrilateral shape with four corners, such as a square, diamond, or rectangle. The die mounting portion has a first thickness. A tie bar segment is attached to each corner of the die mounting portion. Each tie bar segment extends from the die mounting portion to an edge of the semiconductor package. The package has four lead portions. Each individual lead portion is positioned adjacent to a separate side of the die mounting portion. The four lead portions each have a second thickness that is greater than the first thickness of the die mounting portion. The package has a semiconductor die mounted on the die mounting portion and four wire bonds. Each wire bond having a first end bonded to a separate bond pad on the semiconductor die and a second end bonded to a separate lead portion. A molding compound covers the semiconductor die and the bond wires. The molding compound covers at least a portion of the die mounting portion and of the four lead portions.

In an example, the semiconductor package has a rectangular shape and the die mounting portion has a diamond shape generally centered within the semiconductor package. Each of the four lead portions have a sloped side that is generally parallel to a side of the die mounting portion.

The first thickness of the four lead portions may be 8 mil and the second thickness of the die mounting portion may be 4 to 5.5 mil. The first thickness may be a thickness of a leadframe panel used in manufacturing the semiconductor package and the second thickness may be created by partially etching the leadframe panel. The tie bar segments may be attached to each corner of the die mounting portion and have the second thickness that is created by partially etching the leadframe panel.

A notch may be created in one side of the die mounting portion.

A bottom surface of the die mounting portion and bottom surfaces of the four lead portions may be exposed through the molding compound. The tie bar segments attached to each corner of the die mounting portion and contact tie bars attached the four lead portions may be exposed through the molding compound on sides of the semiconductor package.

In another arrangement, an IC package comprises a die attach pad (DAP) having a diamond shape with four corners. The DAP having a first thickness. At least one tie bar segment is attached to a corner of the DAP. The at least one tie bar segment extends from the DAP to an edge of the IC package. The IC package has at least one contact portion. The at least one contact portion is positioned adjacent to a side of the DAP. The at least one contact portions has a second thickness that is greater than the first thickness of the DAP. A semiconductor die is mounted on the DAP. In the IC package, a wire bond has a first end bonded to a bond pad on the semiconductor die and a second end bonded to a selected one of the at least one contact portion. A molding compound covers the semiconductor die and the bond wire, and the molding compound covering at least a portion of the DAP and of the at least one contact portion.

The IC package may have a rectangular shape with the DAP generally centered within the IC package and the at least one contact portion located near a corner of the IC package. The at least one contact portion may have a side that is generally parallel to a side of the DAP.

The first thickness of the at least one contact portion may be 8 mil, and the second thickness of the DAP may be 4 to 5 mil. The first thickness may be a thickness of a leadframe panel used in manufacturing the IC package, and the second thickness may be created by partially etching the leadframe panel. The at least one tie bar segment attached to the corner of the DAP may have the second thickness. Additional tie bar segments may be attached to the at least one contact portion. The additional tie bar segments may have a third thickness that is created by partially etching the leadframe panel.

The IC package may have a notch in one side of the DAP adjacent to the at least one contact portion.

A bottom surface of the DAP and a bottom the at least one contact portion may be exposed through the molding compound. The at least one tie bar segment attached to the corner of the DAP and the additional tie bar segments attached to the at least one contact portion may also be exposed through the molding compound on sides of the IC package.

The IC may be a Quad Flat No-lead (QFN) package with four or more contacts.

While various examples of the present disclosure have been described above, it should be understood that they have been presented by way of example only and not limitation. Numerous changes to the disclosed examples can be made in accordance with the disclosure herein without departing from the spirit or scope of the disclosure. Modifications are possible in the described embodiments, and other embodiments are possible, within the scope of the claims. Thus, the breadth and scope of the present invention should not be limited by any of the examples described above. Rather, the scope of the disclosure should be defined in accordance with the following claims and their equivalents.

What is claimed is:

1. A semiconductor package, comprising:
a die mounting portion having a quadrilateral shape with four corners, the die mounting portion having a first thickness;
a tie bar segment attached to each corner of the die mounting portion, each tie bar segment extending from the die mounting portion to an edge of the semiconductor package;
four lead portions, wherein each individual lead portion is positioned adjacent to a separate side of the die mounting portion, the four lead portions each having a second thickness that is greater than the first thickness of the die mounting portion;
a semiconductor die mounted on the die mounting portion;
four wire bonds, each wire bond having a first end bonded to a separate bond pad on the semiconductor die and a second end bonded to a separate lead portion; and
a molding compound covering the semiconductor die and the wire bonds, the molding compound covering at least a portion of the die mounting portion and of the four lead portions.

2. The semiconductor package of claim 1, wherein the semiconductor package has a rectangular shape and the die mounting portion has a diamond shape generally centered within the semiconductor package.

3. The semiconductor package of claim 2, wherein each of the four lead portions have a sloped side that is generally parallel to a side of the die mounting portion.

4. The semiconductor package of claim 1, wherein the first thickness of the four lead portions is 8 mil and the second thickness of the die mounting portion is 4 to 5 mil.

5. The semiconductor package of claim 1, wherein the first thickness is a thickness of a leadframe panel used in manufacturing the semiconductor package and the second thickness is created by partially etching the leadframe panel.

6. The semiconductor package of claim 5, wherein the tie bar segments attached to each corner of the die mounting portion has the second thickness that is created by partially etching the leadframe panel.

7. The semiconductor package of claim 1, further comprising:
a notch in one side of the die mounting portion.

8. The semiconductor package of claim 1, wherein a bottom surface of the die mounting portion and bottom surfaces of the four lead portions are exposed through the molding compound.

9. The semiconductor package of claim 5, wherein the tie bar segments attached to each corner of the die mounting portion and contact tie bars attached the four lead portions are exposed through the molding compound on sides of the semiconductor package.

10. An integrated circuit (IC) package, comprising:
a die attach pad (DAP) having a diamond shape with four corners, the DAP having a first thickness;
at least one tie bar segment attached to a corner of the DAP, the at least one tie bar segment extending from the DAP to an edge of the IC package;
at least one contact portion, wherein the at least one contact portion is positioned adjacent to a side of the DAP, the at least one contact portions having a second thickness that is greater than the first thickness of the DAP;
a semiconductor die mounted on the DAP;
a wire bond having a first end bonded to a bond pad on the semiconductor die and a second end bonded to a selected one of the at least one contact portion; and
a molding compound covering the semiconductor die and the wire bond, the molding compound covering at least a portion of the DAP and of the at least one contact portion.

11. The IC package of claim 10, wherein the IC package has a rectangular shape with the DAP generally centered within the IC package and the at least one contact portion located near a corner of the IC package.

12. The IC package of claim 11, wherein the at least one contact portion has a side that is generally parallel to a side of the DAP.

13. The IC package of claim 10, wherein the first thickness of the at least one contact portion is 8 mil and the second thickness of the DAP is 4 to 5 mil.

14. The IC package of claim 10, wherein the first thickness is a thickness of a leadframe panel used in manufacturing the IC package and the second thickness is created by partially etching the leadframe panel.

15. The IC package of claim 14, wherein the at least one tie bar segment attached to the corner of the DAP has the second thickness.

16. The IC package of claim 14, further comprising:
additional tie bar segments attached to the at least one contact portion, wherein the additional tie bar segments have a third thickness that is created by partially etching the leadframe panel.

17. The IC package of claim 10, further comprising:
a notch in one side of the DAP adjacent to the at least one contact portion.

18. The IC package of claim 10, wherein a bottom surface of the DAP and a bottom the at least one contact portion is exposed through the molding compound.

19. The IC package of claim 16, wherein the at least one tie bar segment attached to the corner of the DAP and the additional tie bar segments attached to the at least one contact portion are exposed through the molding compound on sides of the IC package.

20. The IC package of claim 10, wherein the IC package comprises a Quad Flat No-lead (QFN) package with four contacts.
